(19) United States
(12) Patent Application Publication
(10) Pub. No.: US 2018/0190712 A1
(43) Pub. Date: Jul. 5, 2018

(54) Semiconductor LED Display Devices

(71) Applicants: Fang Xu, Irvine, CA (US); Xijuan Zhang, Tianjin (CN)

(72) Inventors: Fang Xu, Irvine, CA (US); Xijuan Zhang, Tianjin (CN)

(21) Appl. No.: 15/422,464

(22) Filed: Feb. 2, 2017

(30) Foreign Application Priority Data
Dec. 31, 2016 (CN) 201611263484.4

(51) Int. Cl. H01L 27/15; H01L 25/16; H01L 33/62; H01L 33/00; H01L 33/32; H01L 33/50; H01L 33/42; H01L 33/12; H01L 33/06

(52) U.S. Cl. CPC H01L 27/156; H01L 25/167; H01L 33/62; H01L 33/0079; H01L 33/06; H01L 33/32; H01L 33/502; H01L 33/42; H01L 33/12; H01L 33/0012

(57) ABSTRACT

The subject of this invention is a full-color display device based on III-Nitride semiconductors. The display device includes an array of micro-LEDs, monolithically integrated on a single chip of the epitaxially grown LED heterostructure, and flip-chip bonded to a silicon backplane of active matrix driving circuits, and color conversion layers. The LED substrate of the micro-LED array is removed, and the n-regions of the p-n or p-i-n heterojunctions of the micro-LEDs are connected via a thin n-type III-nitride epitaxial layer less than 20 μm thick. The surface of the thin n-type III-nitride epitaxial layer is covered with a layer of transparent/semi-transparent conductive material, forming the common n-type electrode of the micro-LED devices, rendering the vertical current flow in the micro-LED emitters. Each addressing and driving pixel of the active matrix driving circuits contains at least a switching transistor, a switching-driving transistor, and a latch register.

### BACKGROUND OF THE INVENTION

Embodiments of the present invention relates to semiconductor display devices. More particular embodiments of the present invention relate to a full-color display device based on III-nitride semiconductors.

In recent years, advances in III-Nitride semiconductor crystal growth and device processing have led to a series of breakthroughs in high-efficiency and high-power LED manufacturing, high-performance packaging, as well as the continuous reduction of the production costs. It has been predicted that the III-Nitride micro-LED-based display technology will outperform the liquid-crystal-on-silicon (LCOS) and Organic-LED (OLED) display technologies by virtue of the superior optical, electrical and mechanical properties of III-Nitride crystalline semiconductors. Currently, one of the major hurdles along the roadmap of III-Nitride micro-LED display development is the difficulty of achieving full-color display. This arises from the challenges of fabricating, on a single substrate, high-quality red, green and blue LED devices from the same epitaxial LED heterostructure.

The technologies currently used to achieve colorful display with III-Nitride LEDs can be grouped into the following two major categories: For the first category, an array of alternating red, green and blue (RGB) LEDs is formed by assembling, on a backplane board of matrix driving circuits, different mono-color LED devices that are physically separated from each other. The matrix driving circuits comprise either thin film transistors or complementary metal-oxide-semiconductor (CMOS) structures, and function to address each individual LED devices in the array for driving. Full-color display is achieved by individually driving those mono-color LEDs that are assembled on the backplane board and electrically connected to the matrix driving circuitry thereof (U.S. Ser. No. 09/343,448, PCT/EP2015/067749, PCT/US2009/069383, PCT/EP2015/067751). For the second category, a plurality of pixelated micro-LEDs are monolithically integrated and share the same crystalline LED substrate. The micro-LEDs emit short wavelengths in UV or violet colors, and are patterned into matrix arrays. Both the n-type and p-type electrodes of the micro-LEDs are located on the same side of the device that is opposite to the LED substrate, entailing the lateral device current flow parallel with the LED substrate. The micro-LED array is flip-chip bonded to a silicon backplane of CMOS active matrix driving and addressing circuits, with the electrodes of each micro-LED pixel connected to the electrodes of the corresponding addressing circuit via eutectic metal bonding. A matrix array of alternating red, green or blue phosphor coatings is deposited and patterned over the LED substrate, and aligned with the micro-LED array across the transparent substrate. The short wavelength emission of each micro-LED passes through the transparent substrate and excites the corresponding phosphor coating for color conversion, which leads to the full-color display (U.S. Ser. No. 09/047,818, U.S. Ser. No. 09/111,464).

There remain a number of drawbacks for those existing III-Nitride LED colorful display technologies which largely arise from the structural configuration of the display devices employed to date: In the first aforementioned technology category, the LED dies or chips constituting the display panel are physically separated from each other although they are assembled and anchored on the same backplane board or silicon substrate for active matrix addressing and driving. It is difficult to reduce the separating distance (≥10 μm) between those neighboring discrete devices, leading to large pixel pitch and hence low resolution of the colorful display panels (≤300 ppi) demonstrated to date. The second existing technology involves monolithically integrating, on the same LED substrate, a plurality of pixelated micro-LED devices, which are separated by dry-etched airgaps as narrow as micrometer- or sub-micrometer in width. Nevertheless, the presence of the LED substrate in the display device configuration has resulted in two problems: first, the color conversion phosphor cells are separated from the emission region of the micro-LEDs by the relatively thick substrate (≥80 μm). As light emission from each micro-LED travels through the substrate along the normal direction to reach the overlaid phosphor coating, the light spread out laterally to the phosphor coatings on top of the nearby micro-LEDs upon small separation of pixelated micro-LEDs (≤50 μm), due to the divergence of the micro-LED emission. This causes significant crosstalk between the neighboring display pixels and pose severe limitations to the display resolution (≤500 ppi) , as analyzed in the detailed description section of this patent disclosure. Secondly, the common LED substrate, such as sapphire, for III-nitride devices is insulating, entailing the lateral current flow in the micro-LEDs, which leads to high working voltage and hence low efficiency and non-uniform operation of the pixelated micro-LED emitters. Additionally, the CMOS active matrix backplane circuits employed in the existing III-Nitride display technologies often have the grey-level signals stored in the MOS capacitors. The charge leakage of those capacitors leads to the shift of the gate bias of the driving transistors and hence the variation of the current flow in the micro-LED loads. The micro-LED brightness fluctuates accordingly, causing the inaccuracy of the pixel grey-levels in the display.

### BRIEF SUMMARY OF THE INVENTION

A III-Nitride semiconductor based full-color LED display device is described. In an embodiment, the full-color LED display device comprises an array of micro-LEDs that are monolithically integrated on the single chip of an epitaxially grown III-nitride LED heterostructure, and a silicon backplane of active matrix circuits. The micro-LEDs in the array emit light at UV or violet or blue wavelengths. The silicon backplane of active matrix circuits contains a plurality of addressing and driving pixels.

In an embodiment, the substrate of the LED chip containing the array of micro-LED emitters is removed, and the n-regions of the p-n or p-i-n heterojunctions of all of the micro-LED devices are connected via a thin n-type III-nitride epitaxial layer less than 20 μm thick.

In an embodiment, the surface of the thin n-type III-nitride epitaxial layer is overlaid with a layer of transparent or semi-transparent conductive material, forming the n-type surface electrode of the micro-LEDs. The n-type surface electrode further connects to the cathode of the silicon backplane circuits via metal interconnects, which renders the vertical current flow in the micro-LED emitters normal to the surface of the LED epitaxial layers.

In an embodiment, an array of color-conversion layers is patterned and placed over the n-type III-nitride epitaxial layer, and spatially aligned with the micro-LEDs on the other side of the n-type III-nitride epitaxial layer. Each color conversion layer is formed over only one micro-LED, and separated from the quantum-well emissive region of the micro-LED by a distance substantially less than the substrate of the LED chip. In an embodiment, the p-type electrode of each micro-LED in the array is electrically connected to the anode of the corresponding addressing and driving pixel in the active matrix circuits of the silicon backplane, and the number of addressing and driving pixels equals the number of micro-LEDs in the array.

In an embodiment, each addressing and driving pixel in the active matrix circuits of the silicon backplane contains at least one switching transistor, one switching-driving transistor, and a latch register. Among them, the latch register stores the gray level signals. The switching-driving transistor has one of its terminal connected to the p-type electrode of a micro-LED, and the other terminal connected to a current source. In this way, each micro-LED is addressed individually by the corresponding addressing and driving pixel. In an embodiment, the monolithically integrated micro-LEDs in the array are addressed and driven by the active matrix driving circuits of the silicon backplane to emit UV or violet or blue short-wavelength light at different intensities representing different grey levels of the display pixels. The color conversion layers over the micro-LEDs further convert the short-wavelength emission of the micro-LED arra_{y} to the colorful display.

The invention described in this disclosure overcomes some existing problems of III-nitride LED displays by achieving, on the same III-nitride display device, high density array of micro-LEDs that are monolithically integrated, reduced lateral light spreading of the micro-LED emission in the color conversion layer, latched storage of video signals, vertical current transport in micro-LEDs, and uniform micro-LED emission across the array. Those features lead to a full-color display device of high resolution, high contrast, improved uniformity and high efficiency.

It should be appreciated that the foregoing concepts, and additional concepts discussed below, may be arranged in any suitable combination, as the present disclosure is not limited in thus respect. Further, other advantages and novel features of the present disclosure will become apparent from the following detailed description of various non-limiting embodiments when considered in conjunction with the accompanying figures.

### BRIEF DESCRIPTION OF DRAWINGS

FIG. 1 is a cross-sectional view illustration of one type of full-color display device based on III-nitride micro-LEDs according to the invention.

FIG. 2 is a cross-sectional view illustration of another type of full-color display device based on III-nitride micro-LEDs according to the invention.

FIG. 3 is a close-up view of the schematic structure of Region A in FIG. 1.

FIG. 4 shows schematically the lateral spreading of the micro-LED emission traveling through the epitaxial LED heterostructure and the substrate.

FIG. 5 shows the circuit schematic of the addressing and driving pixel of the silicon backplane of active matrix driving circuits in the full-color micro-LED display device according to the invention.

FIG. 6-14 show, respectively, the cross-sectional structure schematic with respect to the multiple processing steps during the fabrication of the full-color micro-LED display device.

FIG. 15 shows the circuit schematic of a type of the latch register used in the addressing and driving pixel of the silicon backplane of active matrix driving circuits in the full-color micro-LED display device according to one embodiment of the invention.

FIG. 16 shows the circuit schematic of an alternative type of the latch register used in the addressing and driving pixel of the silicon backplane of active matrix driving circuits in the full-color micro-LED display device according to one embodiment of the invention.

### DETAILED DESCRIPTION OF THE INVENTION

Embodiments of the present invention relates to semiconductor display devices. More particular embodiments of the present invention relate to a full-color display device based on III-nitride semiconductors. The present invention is designed to addresses some existing problems of III-nitride LED displays, including the low resolution due to pixel pitch size and light spreading in the color conversion layer, non-uniform emission across the array of display pixels, low power efficiency, and limited gray scale.

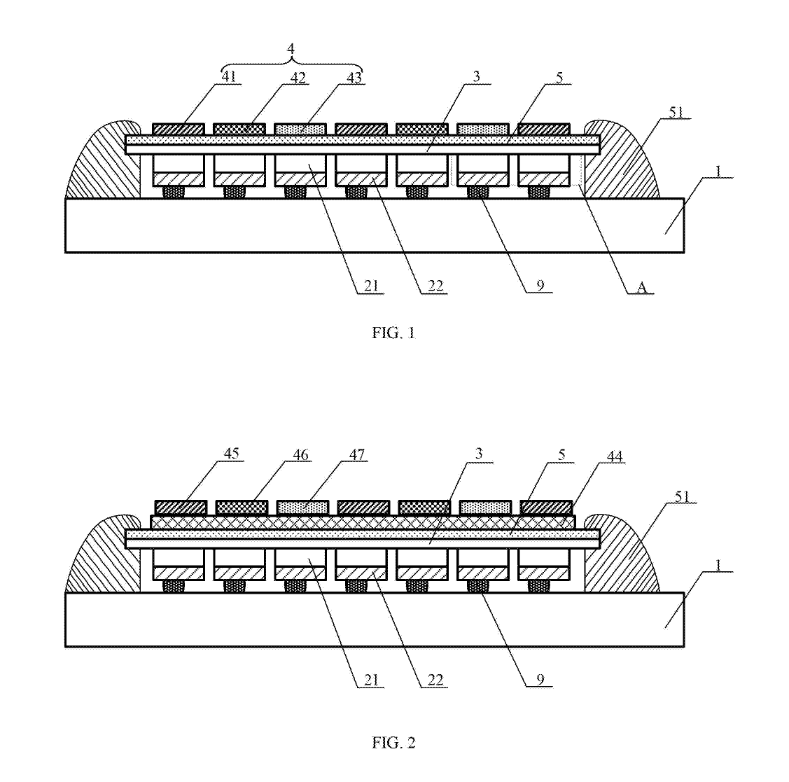

According to one aspect of the present invention, the full-color LED display device, as illustrated in FIGS. 1-6, comprises an array of micro-LEDs that are monolithically integrated on the single chip of an epitaxially grown III-nitride LED heterostructure, and a silicon backplane 1 of active matrix circuits. The active matrix circuits include a plurality of addressing and driving pixels 11. The substrate of the LED chip shared by the micro-LEDs 2 in the array is removed, and the n-regions of the p-n or p-i-n heterojunctions of all of the micro-LEDs are connected via a thin n-type III-nitride epitaxial layer 3 of a thickness ≤20 μm. The full-color LED display device also contains an array of color conversion layers that is patterned and placed over the n-type III-nitride layer 3, and is spatially aligned with the micro-LEDs 2. The micro-LEDs 2 emit short wavelength light at UV or violet or blue wavelengths, which is converted to red, green and blue colors by the color conversion layers for full-color display.

In an embodiment, the micro-LED array is connected to the active matrix circuits by flip-chip bonding the LED heterostructure to the silicon backplane, as illustrated in FIGS. 1-3. The p-type electrode 22 of each micro-LED 2 in the array is electrically connected, via the bonding bump 9, to the anode of the corresponding addressing and driving pixel in the active matrix circuits. The flip-chip bonding is accomplished with metallic or adhesive bonding materials, such as, but does not limit to, Au, Al, Ag, Pb, AuSn, AgSn, Agln, Cu, In or an anisotropic conductive film (ACF). The total number of addressing and driving pixels of the active matrix circuits on the silicon backplane 1 equals the total number of micro-LEDs 2 in the micro-LED array of the LED display device.

According to another aspect of the present invention, the micro-LEDs 2 in the array are fabricated from the same LED substrate, which renders the capability of high-density monolithic integration of the micro-LEDs on the LED display chip. The substrate of the LED chip is removed during the device processing, exposing a layer of n-type III-nitride epitaxial layer 3 of a thickness of ≤20 μm, which connects all of the micro-LEDs in the array, as illustrated in FIGS. 1-3. The n-type III-nitride layer 3 may comprise at least one element from the group consisting of GaN , AlN , AlGaN , InGaN , InAlN , InAlGaN, and may include more than one layer. The exposed surface of the n-type III-nitride epitaxial layer 3 is further deposited with a transparent or semi-transparent conductive material to form the n-type surface electrode 5 of the micro-LEDs. The n-type surface electrode 5 is made of conductive materials, such as Cr, Ni, Au, Ag, Al, Pt, ITO, SnO, ZnO, graphene, and their alloys. The n-type surface electrode 5 of the micro-LEDs on the n-type III-nitride epitaxial layer further connects to the cathode of the active matrix circuits on the silicon backplane via the metal interconnects 51. Since the micro-LED array is bonded to the silicon backplane 1 upside down such that the p-type electrodes 22 of the micro-LEDs face-to-face connect to the anodes of the active matrix circuits on the silicon backplane, light radiation from the emissive region 21 of the micro-LEDs exits the devices from the n-type III-nitride epitaxial layer 3 and the transparent or semi-transparent n-type surface electrode 5 thereon. The Ohmic metal that forms the p-type electrodes 22 of the micro-LEDs may partially reflect the light to the n-type III-nitride epitaxial layer 3 for output coupling.

In an embodiment, an array of alternating red and green and blue (RGB) color conversion layers (41 for red, 42 for green and 43 for blue) is patterned and placed over the n-type III-nitride epitaxial layer and the transparent or semi-transparent electrode thereon, as illustrated in FIG. 1. The color-conversion layers 41, 42 & 43 are made of materials such as, but not limit to, inorganic phosphors and fluorescent materials, organic dyes, organic phosphoric and fluorescent molecules, or inorganic nanocrystalline semiconductors. The array of alternating red and green and blue (RGB) color-conversion layers 41 & 42 & 43 is spatially aligned with the emissive regions (quantum-wells and p-type III-nitride epitaxial layers) 21 of the arrayed micro-LEDs on the other side of the n-type III-nitride epitaxial layer 3. Each color conversion layer is formed over only one micro-LED. An insulating and transparent film may optionally be inserted between the transparent or semi-transparent electrode 5 and the color conversion layers 41 & 42 & 43. The insulating and transparent film may be formed of a variety of insulating materials, such as, but not limit to, inorganic dielectric materials and organic molecules, and may include more than one layer of film. Alternatively, both of the transparent or semi-transparent electrode 5 and the insulating and transparent film may be optionally absent from the display device structure such that the color-conversion layers 41 & 42 & 43 are placed in direct contact with the n-type III-nitride epitaxial layer 3 for a simplified device configuration.

The alternating RGB color conversion layers 41 & 42 & 43 are separated from the emissive regions 21 of the micro-LEDs by a distance substantially less than the thickness of the substrate of the LED heterostructure. Upon short wavelength (blue or UV or violet) excitation with the micro-LEDs 2, the red, green, and blue color conversion layers 41 & 42 & 43 convert the short-wavelength emission of the micro-LEDs to red, green and blue light, respectively. In this manner, alternating red, green and blue emissive pixels are formed, leading to the colorful panel of the display. The thickness of the color conversion layers 41 & 42 & 43 should be kept less than 5 times of the pitch of the display pixels to minimize the cross-talk between the neighboring display pixels.

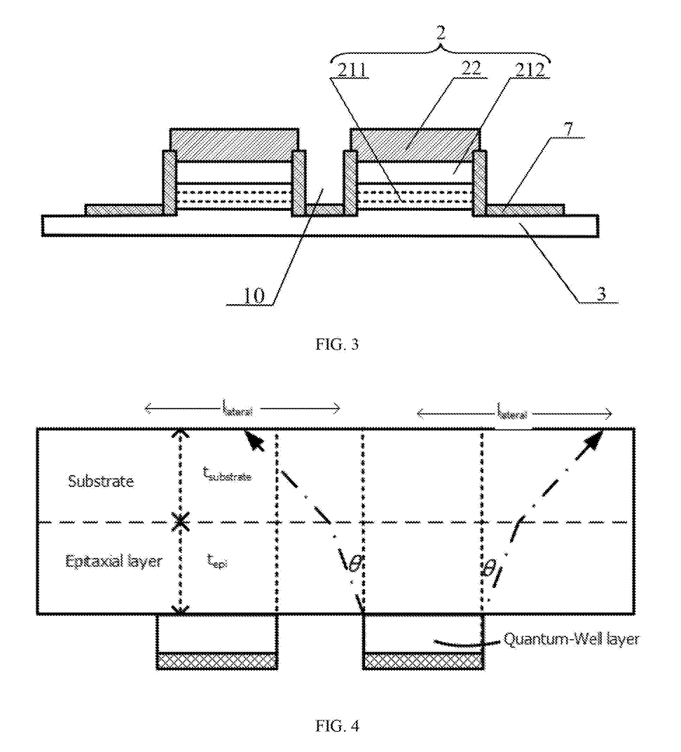

In an embodiment, a layer of white color conversion material 44 is placed over the n-type III-nitride epitaxial layer 3 and the transparent or semi-transparent surface electrode 5 thereon, as illustrated in FIG. 2. The white color conversion layer 44 is made of the material such as, but not limit to, inorganic phosphors and fluorescent materials, organic dyes, organic phosphoric and fluorescent molecules, or inorganic nanocrystalline semiconductors. An array of alternating red and green and blue (RGB) color filters (45 for the red filter, 46 for the green filter and 47 for the blue filter) is placed over the white light conversion layer 44, and is spatially aligned with the emissive regions (quantum-wells and p-type III-nitride epitaxial layers) 21 of the arrayed micro-LEDs on the other side of the n-type III-nitride epitaxial layer 3. Each color filter is formed over only one micro-LED. The RGB color filters 45 & 46 & 47 may be made of organic molecules or inorganic dielectric films, which filter the incoming white light to red, green and blue transmission via absorption or reflection of the rejected colors. An insulating and transparent film may optionally be inserted between the transparent semi-transparent surface electrode 5 and the white light conversion layer 44. The insulating and transparent film may be formed of a variety of insulating materials, such as, but not limit to, inorganic dielectric materials and organic molecules, and may include more than one layer of film. Alternatively, both of the transparent or semi-transparent surface electrode 5 and the insulating and transparent film may be optionally absent from the display device structure such that the white color conversion layer 44 are placed in direct contact with the n-type III-nitride epitaxial layer 3 for a simplified device configuration.

The white color conversion layer 44 is separated from the emissive regions 21 of the micro-LEDs by a distance substantially less than the thickness of the substrate of the LED chip. Upon UV or violet excitation with the micro-LEDs, the white color conversion layer and the RGB color filters work together to convert the short-wavelength emission of the micro-LEDs to red, green and blue light, respectively. In this manner, alternating red, green and blue emissive pixels are formed, leading to the color panel of the display. The thickness of the white color conversion layer 44 should be kept less than 5 times of the pitch of the display pixels to minimize the cross-talk between the neighboring display pixels.

In an embodiment, a layer of color conversion material is placed over the n-type III-nitride epitaxial layer 3 and the transparent or semi-transparent surface electrode 5 thereon, wherein the color conversion layers comprising alternating red, green, and blue color-filters, 45 & 46 & 47 , selectively filtering the white emission of the micro-LEDs to generate red, green and blue light, and are spatially aligned with the mesas of the array of micro-LEDs on the other side of the n-type III-nitride epitaxial layer such that each micro-LED is overlaid with only one type of color-filter.

In the embodiments of the present invention, the III-nitride micro-LEDs form dense arrays on the LED chip by virtue of the monolithic integration and the connection of the n-type III-nitride layer of the micro-LEDs. Each micro-LED has its p-type electrode connected to the anode of the corresponding addressing and driving pixel in the active matrix circuit of the silicon backplane, which functions to address and control the current or voltage of that micro-LED device. Consequently, the emission duration time or the light intensity of each micro-LED is controlled individually by the corresponding the addressing and driving pixel in the active matrix circuit, rendering the multiple grey levels of the display pixels. Furthermore, the short wavelength emission of the micro-LEDs in the array excites the arrayed color conversion layers to form alternating red, green and blue pixels with tunable grey levels in the display panel. In this manner, the full-color display is achieved with a desirable gray scale.

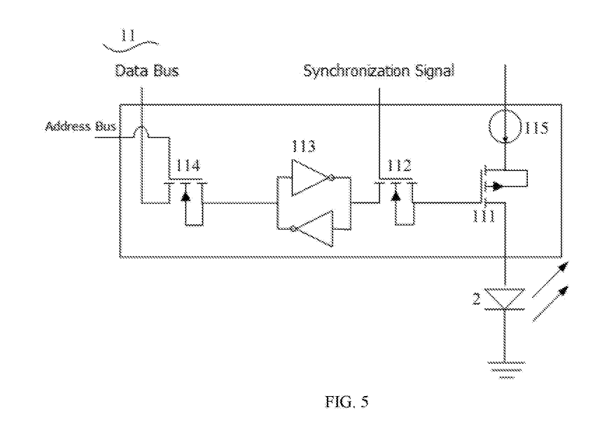

In an embodiment, the III-Nitride LED heterostructure is epitaxially grown on a single crystalline substrate. FIG. 3 shows schematically the LED heterostructure, which includes, from the substrate (which is not included in FIG. 3) up, a III-nitride buffer layer (which is too thin to appear in FIG. 3), a n-type III-nitride epitaxial layer 3 and the emissive region 21. The emissive region further includes the III-nitride quantum-wells 211 and a p-type III-nitride epitaxial layer 212. The crystalline substrate may be, but not limited to Sapphire, SiC, Silicon and GaN wafers.

In an embodiment, mesas of the micro-LEDs are formed by patterning and partially etching the epitaxial layers between the defined mesa regions, which forms the air gaps 10 between the micro-LEDs, as illustrated in FIG. 3. The etching starts from the top p-type epitaxial layer 212 of the LED heterostructure and stops in the n-type III-nitride epitaxial layer 3. The air gap depth is therefore greater than the total thickness of the p-type epitaxial layer 211 and the quantum-well emissive region 212, but less than the overall thickness of the epitaxially grown LED heterostructure. The shape of the mesas may be, but not limited to, square, rectangular, circular or hexagonal. The sidewalls of the mesas are passivated by a layer of insulating materials 7 that include, but not limited to, SiO₂ and SiₓN_{y}. The thickness of the passivation layer 7 is more than 0.1 nm.

In an embodiment, the top surfaces of the p-type III-nitride epitaxial layers 212 of the micro-LED mesas are deposited with p-type Ohmic metals, forming the p-type electrode 22 of the micro-LEDs. The n-type lateral electrode may also be formed in the periphery regions around the micro-LED matrices by depositing n-type Ohmic metals on the etching-exposed n-type III-nitride epitaxial layer. The n-type lateral electrode is shared by all of the micro-LEDs in the array, and entails lateral current flow that is parallel with the epitaxial layers of the LED heterostructure. The thickness of the p-type and n-type Ohmic metals is greater than 0.1 nm, and the Ohmic metals include, but do not limit to Cr, Ni, Au, Ag, Al, Pt, ITO, SnO, ZnO and their alloys.

In the array of monolithically integrated III-nitride micro-LEDs, electrical isolation is achieved by the dry-etching formed air-gaps 10 between the neighboring devices, as shown in FIG. 3. The width of the air gap 10 determines the minimum distance between the micro-LED devices, which, in turn, further poses the ultimate limit of the resolution of the micro-LED based display panels. According to one aspect of the present invention, since the micro-LEDs are monolithically integrated, and share the n-type III-nitride layer in their diode junctions, the depth of the air-gaps 10 only need to be slighter greater than the total thickness of emissive region 21 comprising the multiple quantum-wells 211 and the p-type III-nitride layer 212. Since the total thickness of the emissive region 21 of III-nitride micro-LEDs is typically between 0.001-3 μm, the depth of the air-gaps 10 between the micro-LEDs can be made significantly less than the thickness of the LED heterostructure (5-20 μm) over the substrate. The small gap depth helps to keep the dry-etching formed air-gaps 10 very narrow in III-nitrides, rendering the capability of achieving micro-LED arrays of higher density in the present invention than those matrix arrays of fully-separated and discrete LEDs in some previous III-nitride LED display inventions and invention applications (U.S. Ser. No. 09/343,448, PCT/EP2015/067749, PCT/EP2015/067751, PCT/US2009/069383, CN105679196).

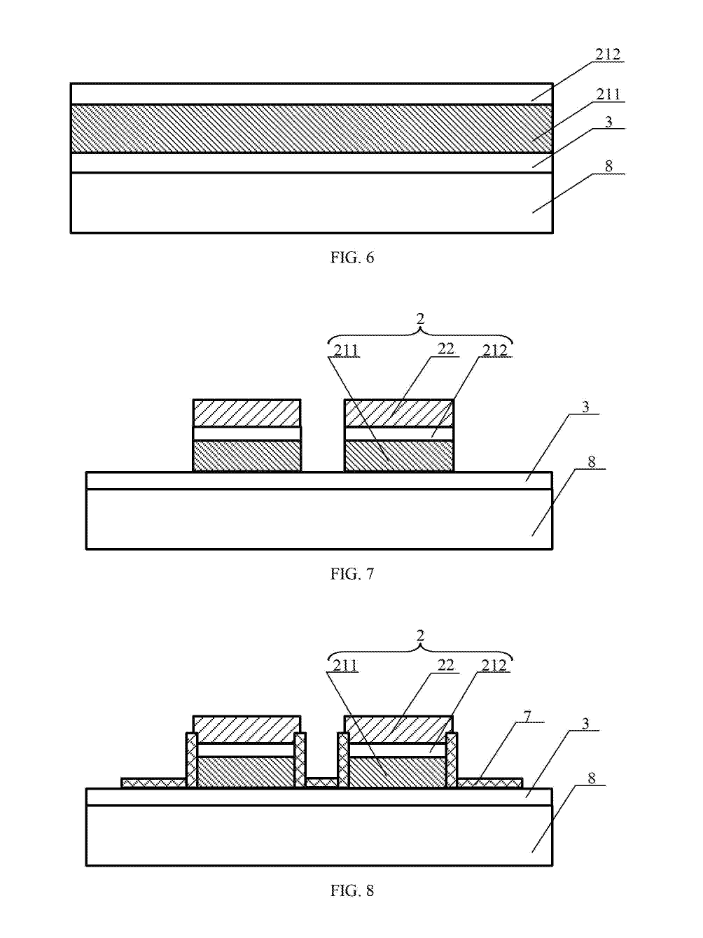

According to another aspect of the present invention, the LED substrate is removed from the III-nitride micro-LED array, the emissive region 21 of every micro-LED separates from the overlaid color conversion layer by a distance close to the thickness of the n-type III-nitride epitaxial layer that is located in between. The emission of the micro-LED travels that distance across the n-type III-nitride epitaxial layer 3 before reaching the color conversion layer 4, as illustrated in FIG. 4. Due to the divergence of the micro-LED emission, the traveling light from each micro-LED also spreads out laterally by a distance:

$${l}_{lateral} = sin θ \cdot {t}_{epi} + sin θ \cdot \frac{{n}_{epi}}{{n}_{substrate}} \cdot {t}_{substrate} \qquad ( 1 )$$

Where lₗₐₜₑᵣₐₗ is the lateral spreading distance of the micro-LED emission, ⊖ is the half divergence angle of the micro-LED emission inside the III-nitride layers, nₑₚᵢ and n_{substrate} are the refractive indices of the n-type III-nitride epitaxial layer 3 and the substrate, respectively, tₑₚᵢ and t_{substarte} are the thicknesses of the n-type III-nitride epitaxial layer and the substrate, respectively. Equation 1 calculates the lateral spreading of the LED emission in the presence of both the substrate and the n-type III-nitride epitaxial layer 3. Since the thickness of the n-type III-nitride epitaxial layer 3 (≤20 μm) is significantly less than that of the substrate (≥80 μm), it is evident from Eq. 1 that the removal of the substrate; dramatically reduce the lateral spreading of the micro-LED emission, and consequently reduce the cross-talk between the neighboring pixels in the display panel.

According to yet another aspect, one surface of the n-type III-nitride epitaxial layer 3 that connecting the diode junctions of the micro-LEDs in the array is deposited with a transparent or semi-transparent conductive material to form the n-type surface electrode 5 of the micro-LEDs, as illustrated in FIGS. 1-3. The n-type surface electrode 5 gives rise to the vertical transport of the driving current in the micro-LEDs, and resolves the large bulk resistance and non-uniform current distribution problems of the micro-LED arrays relying on lateral current flow in the other patented technologies (U.S. Ser. No. 09/047,818, U.S. Ser. No. 09/111,464).

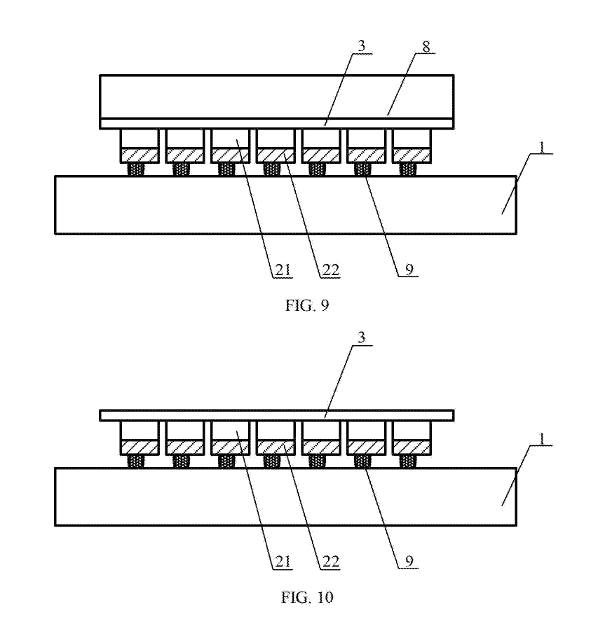

In an embodiment, each addressing and driving pixel of the active matrix circuits on the silicon backplane contains at least one switching transistor 114, one switching-driving transistor 111, and a latch register 113, as illustrated in FIG. 5. Among them, the switching-driving transistor has one of its terminal connected to the p-type electrode of a micro-LED, and the other terminal connected to a current source, by which the micro-LED is addressed individually by the addressing and driving pixel in the colorful display panel. The latch register 113 stores the gray level signals from the data bus, and delivers the signal to the gate terminal of the switching-driving transistor to control the pulse duration or amplitude of the current flow in the micro-LEDs. The pixels of the LED display device present different grey levels for different pulse durations or amplitudes of the current flow in the micro-LEDs.

It is concluded that the aforementioned device structures in this disclosure lead to a full-color display device based on monolithically integrated III-nitride LEDs, which exhibits the potential of high resolution, high contrast, improved uniformity and high efficiency.

The following example, in combination with the figures, serves to offer a detailed illustration to the design and fabrication of the III-nitride miro-LEDs based full-color display device of the present invention by those who skilled in the art. The example, however, by no means limits the present invention. While specific values and specific material compositions are noted in the example, it should be understood that the areas used are processing technique specific, and that the current disclosure is not limited to just the values and compositions disclosed in the example. The figures are diagrammatic and not drawn to scale. In the figures, elements which correspond to elements already described have the same reference numerals.

In this example, the display device includes an array of high-density micro-LED emitters that are monolithically integrated on a single LED chip, the substrate of which is removed, a silicon backplane of active matrix driving circuits, and the color conversion layers. The schematic structures of the display panel devices are illustrated in FIGS. 1 and 2. Among them, FIG. 1 shows the device structure containing the array of RGB color conversion layers, and FIG. 2 shows another device structure containing the white color conversion layer and RGB filters.

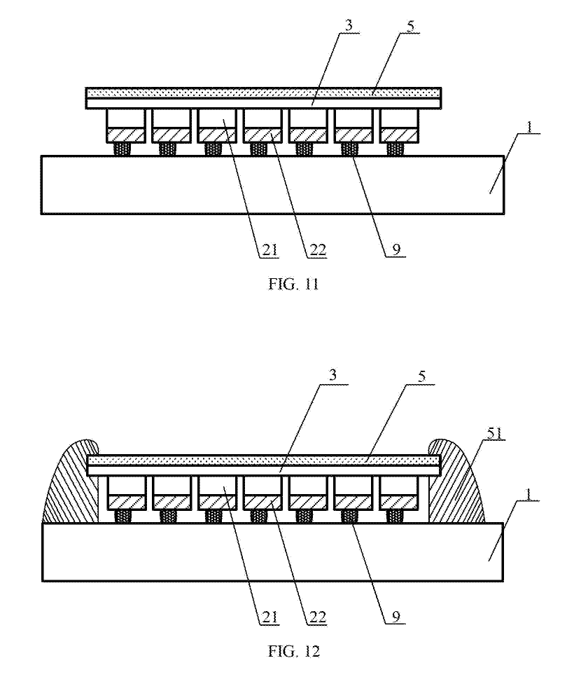

FIGS. 6-8 illustrates the first several processing steps for the fabrication of the micro-LED devices of the short-wavelength LED heterostructure, taking the example of a sapphire substrate. This includes:
1. Epitaxial growth of the III-nitride LED heterostructure on a sapphire substrate 8, as illustrated in FIG. 6. The heterostructure includes, from bottom up on the sapphire substrate 8, a III-nitride buffer layer (which is too thin to appear in FIG. 6), a n-type III-nitride epitaxial layer 3, the emissive III-nitride quantum-wells 211, and a p-type III-nitride epitaxial layer 212.
2. FIG. 7 shows the dry etching into the epitaxial layers of the LED hetersructure to form the micro-LED mesas and the air gaps 10 between the mesas, and to expose the n-type epitaxial layer 3 around the mesa matrices. The etch starts from the top surface of the p-type III-nitride epitaxial layer 212, through the emissive III-nitride quantum-wells 211, and stops in the n-type III-nitride epitaxial layer 3, with an etching depth of 1.5 um. In this example, the surface of the micro-LED mesa takes the square shape with a surface area of 10 um×10 um. The width of the air gaps 10 between the neighboring micro-LEDs is 2 um.
3. FIG. 8 shows the deposition and patterning of the SiO₂ passivation layer 7 over the micro-LED mesas to passivate the sidewalls. The SiO₂ layer on the top p-type III-nitride layer of the micro-LEDs 212 is removed to open windows for the formation of p-type electrodes 22 via photolithography and dry etching. In the same processing step, the SiO₂ layer over regions of the n-type epitaxial layer 3 around the mesa array is also removed to open windows for the formation of n-type lateral electrode of the micro-LEDs.
4. As illustrated with FIG. 8, vacuum evaporation and liftoff processes are used to deposit Cr/Pt/Au (10 nm/100 nm/300 nm) Ohmic metals in the window openings of the SiO₂ on the top p-type III-nitride layer of the micro-LEDs and along the regions of n-type expiaxial layer around the mesa array to form the p-type electrodes 22 and the n-type lateral electrode of the micro-LEDs, respectively.

FIG. 9-11 represents the subsequent processing steps of the full-color micro-LED display device following the contact formation on the front side. FIG. 9 schematically shows the flip-chip bonding of the micro-LED arrays and the silicon backplane of active matrix driving circuits. The bonding process includes: opening via-holes in the passivation layer on top of the silicon backplane, forming an under-bump-metallurgy (UBM) layer and a bonding bump 9 over each addressing and driving pixels in the active matrix driving circuits of the silicon backplane, flip-chip bonding of the III-nitride micro-LED array to the silicon backplane 1.

FIG. 10 schematically shows the removal of the substrate 8 of the III-nitride micro-LED arrays. The substrate removal can be accomplished with a UV laser lift-off process. Upon the substrate removal, the n-type epitaxial layer 3 of the LED heterostructure is exposed, and connects all of the miro-LEDs in the array, offering the surface for the deposition of the common n-type electrode of the micro-LEDs.

FIG. 11 further illustrates the deposition of transparent or semi-transparent conductive layer over the n-type epitaxial layer that connects all micro-LEDs, forming the common n-type surface electrode 5 of the micro-LED arrays. The transparent or semi-transparent conductive layer forming the n-type surface electrode can be Ni/Au (1 nm/3 nm) or ITO (100 nm) or graphene. As shown in FIG. 12, the common n-type surface electrode 5 further connects to the cathode of the silicon backplane of the active matrix driving circuits via the deposition and patterning of metal interconnects 51, which include Ti/Al/Ti/Au (10 nm/8000 nm/10 nm/2000 nm).

An array of alternating red 41 and green 42 and blue 43 (RGB) color-conversion layers is placed over the n-type III-nitride epitaxial layer 3 and the transparent or semi-transparent electrode 5 thereon, as shown in FIG. 13. The red 41, green 42 and blue 43 conversion layers are red, green and blue phosphors, respectively, in the present example. Using the shadow mask-assisted mist-fabrication technique,(as described in Applied Physics Letters, vol. 92, 2008, pp. 023111-023113,) an array of alternating red and green and blue phosphor layers is selectively spray-deposited and spatially aligned with the array of micro-LED mesas on the other side of the n-type III-nitride epitaxial layer. This step completes the fabrication of the III-nitride full-color micro-LED devices as shown in FIG. 13.

Alternatively, following the processing step illustrated in FIG. 14, a white color conversion layer 44 is placed over the n-type III-nitride epitaxial layer and the transparent or semi-transparent electrode thereon. The white color conversion layer 44 is made of the mixture of dye molecules, and is spin- or spray-coated, from their solution, to form a thin film to convert the blue or UV emission of the LEDs to white light. An array of alternating red 45 and green 46 and blue 47 (RGB) color filters is patterned over the white color conversion layer 44 via inkjet printing, and is spatially aligned with the array of micro-LED mesas on the other side of the n-type III-nitride epitaxial layer 3. The RGB color filters are made of pigments of primary absorption peaks in red, green and blue wavelengths, respectively. Each color filter is formed over only one micro-LED. This step completes the fabrication of the III-nitride full-color micro-LED devices as shown in FIG. 14.

FIG. 5 is the simplified circuit diagram of each addressing and driving pixel in the silicon backplane of active matrix driving circuits. Every addressing and driving pixel contains switching transistors 112 and 114, and switching-driving transistor 111, and latch register 113. The switching-driving transistor 111, which has a p-type channel in this example, has its drain terminal connected to the p-type electrode of a micro-LED device, and the source terminal connected to a current source, and the gate terminal connected to the source terminal of the switching transistor 112, which has a n-type channel in this example. The switching transistor 112 further has its drain terminal connected to the output terminal of the latch register 113, and has its gate terminal connected to the synchronization signal. The switching transistor 114, which has an n-type channel in this example, has its drain terminal connected to the Data Bus, and its gate terminal connected to the Address Bus. When the Address Bus sends an active signal, the transistor 114 receive the grey-level signal from the Data Bus.

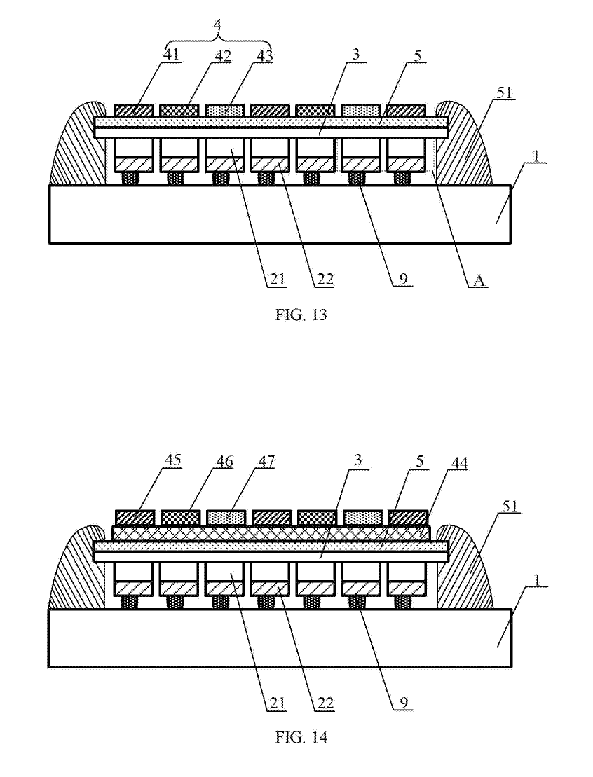

FIG. 15 shows one type of the latch register that can be used in the present example, including p-type MOSFET 1131 and p-channel transistor 1132, n-channel transistor 1133 and n-type transistor 1134. The latch register has its input terminal 1133 connected to the source terminal of the switching transistor 114, receiving the grey-level signals from the transistor 114, and storing the signals. Upon receiving the synchronization active signal, the latch register pass the grey-signal to the gate of the transistor 111 via the output terminal, which in turn controls the amplitude or pulse duration of the current driving the LED, creating the required grey levels of the display pixel.

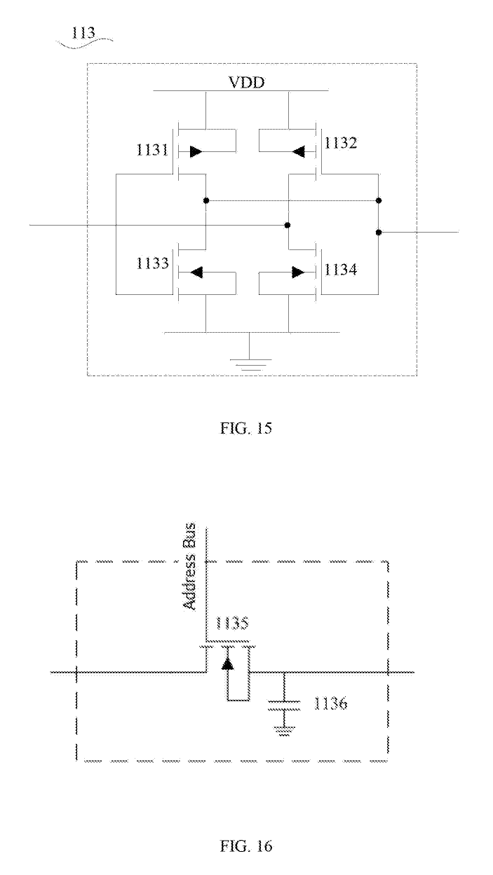

FIG. 16 shows another type of the latch register that can be used in the present example, including a capacitor 1136, an n-type MOSFET 1135. The drain terminal of the MOSFET 1135 is connected to the source of the switching transistor 112. The latch register receive and store the grey-level signal delivered by the transistor 114, and pass the signal to the gate of the transistor 111 upon active synchronization signal, which in turn controls the amplitude or pulse duration of the current driving the LED, creating the desired grey levels of the display pixel.

The invention claimed is:

1. A full color display device based on III-nitride semiconductor LEDs, including:
a monolithically-integrated array of III-nitride micro-LEDs, wherein the substrate of the micro-LEDs being removed, the n-region of the p-i-n (or p-n) heterojunctions of the micro-LEDs being all connected via a thin n-type III-nitride epitaxial layer less than 20 μm thick;
a silicon backplane of active matrix driving circuits that include a plurality of addressing and driving pixels and are connected with the micro-LED array via flip-chip bonding, wherein the anode of each addressing and driving pixel being connected to the p-type electrode of the corresponding micro-LED in the micro-LED array, and the cathode of the silicon backplane of active matrix driving circuits being connected to the n-type electrode of the micro-LED arrays; wherein each addressing and driving pixel including at least two switching transistors, a switching-driving transistor, and a latch register; wherein one terminal of the switching-driving transistor of the addressing and driving pixel functioning as the anode of the addressing and driving pixel and connecting the p-type electrode of the corresponding micro-LED, and the other terminal of the switching-driving transistor of the addressing and driving pixel connecting to a current source;
a number of color conversion layers above the n-type III-nitride epitaxial layer, and separated from the micro-LEDs by a distance less than the thickness of the removed substrate of the micro-LEDs;

2. The full color display device of claim 1, wherein the n-region of the micro-LEDs being all connected via the thin n-type III-nitride epitaxial layer, the surface of the thin n-type III-nitride epitaxial layer is deposited with a layer of transparent or semi-transparent conductive material, forming the n-type surface electrode of the micro-LED array, and pairing with the p-type electrodes of the micro-LEDs to transport current flow in the micro-LEDs vertical to the epitaxial layers of the LED heterostructure, wherein the color conversion layers are placed over the layer of transparent or semi-transparent conductive material, and separated from the micro-LEDs by a distance less than the thickness of the removed substrate of the micro-LEDs;

3. The full color display device of claim 1, wherein the n-regions of the micro-LEDs being all connected via the thin n-type III-nitride epitaxial layer, the surface of the thin n-type III-nitride epitaxial layer is deposited with a layer of transparent or semi-transparent conductive material, forming the surface n-type electrode of the micro-LED array, and pairing with the p-type electrodes of the micro-LEDs to transport current flow in the micro-LEDs vertical to the epitaxial layers of the LED heterostructure, wherein a transparent insulating film is further deposited on the layer of transparent conductive material, the color conversion layers are placed over the transparent insulating film, and separated from the micro-LEDs by a distance less than the thickness of the substrate of the micro-LEDs;

4. The full color display device of claim 1, wherein the n-region of the micro-LEDs being all connected via the thin n-type III-nitride epitaxial layer, the surface of the thin n-type III-nitride epitaxial layer is coated with a transparent insulating film, wherein the color conversion layers are placed over the transparent insulating film, and separated from the micro-LEDs by a distance less than the thickness of the removed substrate of the micro-LEDs;

5. The full color display devices according to the claims 1 & 2 or 1 & 3 or 1 & 4, wherein the color conversion layers comprise layers of alternating red, green and blue converting materials, converting blue or violet or UV emission of the micro-LEDs to red, green and blue light, and are spatially aligned with the mesas of the array of micro-LED on the other side of the n-type III-nitride epitaxial layer such that each micro-LED is overlaid with the color conversion layer of only one color.

6. The full color display device according to any of claim 1 & 2 or 1 & 3 or 1 & 4, wherein the color conversion layers have the layer stack structure, comprising a bottom layer of white conversion layer, converting blue or violet or UV emission of the micro-LEDs to the white light, and the top layer of alternating red, green, and blue color-filters, selectively filtering the white light to generate red, green and blue light, and are spatially aligned with the mesas of the array of micro-LEDs on the other side of the n-type III-nitride epitaxial layer such that each micro-LED is overlaid with only one type of color-filter.

7. The full color display device according to any of claim 1 & 2 or 1 & 3 or 1 & 4, wherein the color conversion layers comprising alternating red, green, and blue color-filters, selectively filtering the white emission of the micro-LEDs to generate red, green and blue light, and are spatially aligned with the mesas of the array of micro-LEDs on the other side of the n-type III-nitride epitaxial layer such that each micro-LED is overlaid with only one type of color-filter.

8. The full color display device of claim 1, wherein the heterostructure of the micro-LEDs is epitaxially grown on a single crystalline substrate that is removed afterwards, and the LED heterostructure includes a III-nitride buffer layer, the n-type III-nitride epitaxial layer, an emissive region of III-nitride quantum-wells, and a top p-type III-nitride epitaxial layer.

9. The full color display device according to the claims 1 & 8, wherein the neighboring micro-LEDs being isolated between each other by air gaps formed by etching into the LED heterostructure from the top p-type III-nitride epitaxial layer with a depth greater than the total thickness of the emissive region of III-nitride quantum-wells and the top p-type III-nitride epitaxial layer, wherein the micro-LEDs having their side walls passivated with layers of insulating materials, having their top surfaces deposited with p-type Ohmic metal for the formation of the p-type electrodes, and having their n-regions all connected with the epitaxial layer of n-type III-nitrides.

10. The full color display device of claim 1, wherein the number of the micro-LEDs in the array matching the number of the addressing and driving pixels of the silicon backplane of active matrix driving circuits, and each micro-LED being addressed individually by each addressing and driving pixel, wherein the latch register of the addressing and driving pixel storing the gray level signals from the data bus, and delivering those signals to the gate terminal of the switching-driving transistor in the addressing and driving pixel to control the pulse duration or density of the current flow in the micro-LEDs, leading to the presentation of different grey levels for different pulse durations or densities of the current flow in the micro-LED array.

11. The full color display device according to claims 1-6 & 8 & 9 & 10, wherein the blue, violet or UV emission of the micro-LEDs in the array exciting the color conversion layers to form alternating red, green and blue pixels with tunable grey levels in the display panel, leading to the full-color display.
